(19) United States
(12) Patent Application Publication
(10) Pub. No.: US 2022/0197148 A1
(43) Pub. Date: Jun. 23, 2022

(54) ELECTRICALLY CONDUCTIVE FILM

(71) Applicant: Cambrios Film Solutions Corporation, Tortola (VG)

(72) Inventors: Pierre-Marc ALLEMAND, Santa Clara, CA (US); Michael Andrew SPAID, Mountain View, CA (US)

(21) Appl. No.: 17/600,773

(22) PCT Filed: Apr. 1, 2020
(86) PCT No.: PCT/US2020/026065

§ 371 Date: Oct. 1, 2021

Related U.S. Application Data
(60) Provisional application No. 62/828,734, filed on Apr. 3, 2019.

(51) Int. Cl. G03F 7/32; G03F 7/004; H01B 1/22; H05K 1/09; H05K 1/02; B32B 37/00

(52) U.S. Cl. CPC G03F 7/322; G03F 7/325; G03F 7/0047; H01B 1/22; B32B 2307/202; H05K 1/0274; B32B 37/025; B32B 2457/208; H05K 1/092

(57) ABSTRACT

A method of forming a transparent, electrically-conductive film and an associated film. The method can be a transfer method. A region of a substrate is provided with a binder that includes metal nanostructures suspended in a photosensitive polymeric material. A donor substrate can be used. Photolithography is used to pattern the binder. The patterned binder is developed using a developing fluid that: (i) removes a portion of the photosensitive polymeric material according to a pattern of the binder, and (ii) includes a nanostructure etchant that etches the metal nanostructures.

### RELATED APPLICATION

This application claims priority to U.S. Provisional Application Ser. No. 62/828,734, titled “ELECTRICALLY CONDUCTIVE FILM” and filed on Apr. 3, 2019, which is incorporated herein by reference.

### FIELD

This disclosure is related to transparent, electrically conductive films, and methods of patterning a nanostructure on a substrate.

### BACKGROUND

Transparent conductors include optically-clear and electrically-conductive films such as those commonly used in touch-sensitive computer displays. Generally, conductive nanostructures overlap each other to form a percolating network having long-range interconnectivity. The percolating network is connected to electronic circuits of a computer, tablet, smart phone, or other computing device having a touch-sensitive display by cooperating (i.e., connecting) with metal contacts.

Transfer films have been used as a means to deposit and pattern silver nanowires on various substrates. In general, a transfer film has a nanowire layer applied to a donor substrate and a photocurable polymer adhesive, also known as a photosensitive binder. The transfer film is placed on a receiver substrate so the photocurable polymer adhesive is supported by the receiver substrate and the photocurable polymer adhesive is photo patterned by exposing and developing to pattern the photocurable polymer adhesive. Uncured portions of the exposed photocurable polymer adhesive are then removed with a solvent or a photoresist stripper. However, residual nanowires previously protected by the now-removed polymer may remain bonded to the receiver substrate, creating the potential for a short circuit between adjacent nanowire lines.

### BRIEF SUMMARY

In accordance with an aspect, the present disclosure provides a transfer method of forming a transparent, electrically-conductive film. A region of a donor substrate is provided with a binder that includes metal nanostructures suspended in a photosensitive polymeric material. The donor substrate and the binder are applied onto a receiver substrate to transfer the binder and the nanowires onto the receiver substrate. The donor substrate can be removed from the binder that was applied onto the receiver substrate either prior light exposure through a mask, or after light exposure. Photolithography is used to pattern the binder. After photoexposure, the binder/nanowires film is developed using a developing fluid that: (i) removes all or a portion of the photosensitive polymeric material according to a pattern of the binder, and (ii) includes a nanostructure etchant that provides for etching of the metal nanostructures.

In accordance with an aspect, the present disclosure provides a method of forming a transparent, electrically-conductive film. A region of a substrate is provided with a binder that includes metal nanostructures suspended in a photosensitive polymeric binder material. Photolithography is used to pattern the binder material. The photo patterned photosensitive polymeric material is developed using a developing fluid that: (i) removes a portion of the photosensitive polymeric material according to a pattern of the binder, and (ii) includes a nanostructure etchant that etches the metal nanostructures.

In accordance with an aspect, the present disclosure provides a transparent, electrically-conductive film. The film includes a substrate and a binder in a pattern on the substrate. The pattern has edges. The film includes metal nanostructures suspended in the binder. Nanostructures at pattern edges are truncated. The pattern has edges created by photolithography wherein binder material and nanostructures are etched off by a solution that includes a component that etches the metal of the nanostructures.

The above summary presents a simplified summary in order to provide a basic understanding of some aspects of the systems and/or methods discussed herein. This summary is not an extensive overview of the systems and/or methods discussed herein. It is not intended to identify key/critical elements or to delineate the scope of such systems and/or methods. Its sole purpose is to present some concepts in a simplified form as a prelude to the more detailed description that is presented later.

### DESCRIPTION OF THE DRAWINGS

While the techniques presented herein may be embodied in alternative forms, the particular embodiments illustrated in the drawings are only a few examples that are supplemental of the description provided herein. These embodiments are not to be interpreted in a limiting manner, such as limiting the claims appended hereto.

The disclosed subject matter may take physical form in certain parts and arrangement of parts, embodiments of which will be described in detail in this specification and illustrated in the accompanying drawings which form a part hereof and wherein:

FIG. 1 is schematic example representation of stages, A-D, that occur in an example method for forming and utilizing a transfer film to create a nanostructure, such as nanowire, film.

FIG. 2 is a schematic example representation of stages included in an example method for forming and utilizing a photo-patternable nanowire film.

FIG. 3 is a flowchart of an example method in accordance with an aspect of the present disclosure.

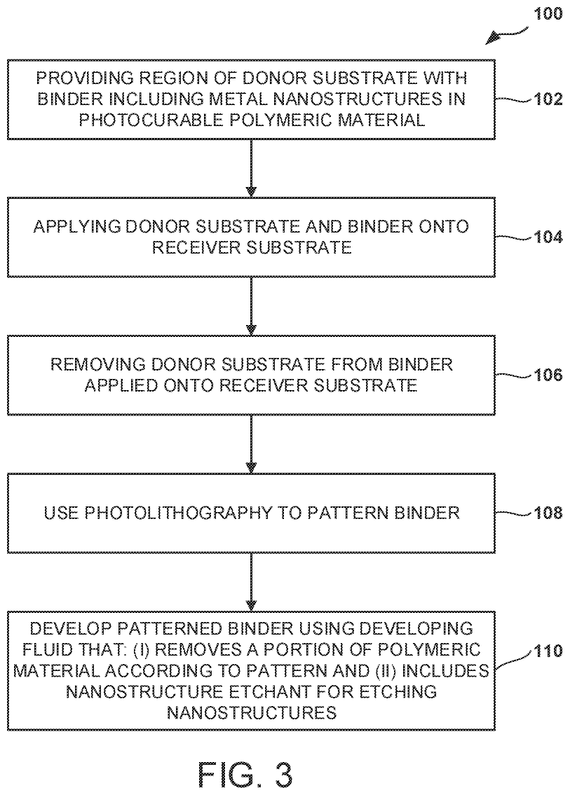

### DETAILED DESCRIPTION

Subject matter will now be described more fully hereinafter with reference to the accompanying drawings, which form a part hereof, and which show, by way of illustration, specific example embodiments. This description is not intended as an extensive or detailed discussion of known concepts. Details that are known generally to those of ordinary skill in the relevant art may have been omitted, or may be handled in summary fashion.

Certain terminology is used herein for convenience only and is not to be taken as a limitation on the disclosed subject matter. Relative language used herein is best understood with reference to the drawings, in which like numerals are used to identify like or similar items. Further, in the drawings, certain features may be shown in somewhat schematic form.

The following subject matter may be embodied in a variety of different forms, such as methods, devices, components, and/or systems. Accordingly, this subject matter is not intended to be construed as limited to any illustrative embodiments set forth herein as examples. Rather, the embodiments are provided herein merely to be illustrative.

Provided herein is a method of forming and using a transfer film including a photopatternable overcoat matrix. The overcoat matrix can be patterned using a developing solution containing an etchant for metallic nanostructures. Also provided herein is transparent, electrically-conductive film made by the method.

As used herein, “conductive nanostructures” or “nanostructures” generally refer to electrically conductive nano-sized structures, at least one dimension of which is less than 500 nm, or less than 250 nm, 100 nm, 50 nm or 25 nm, for example. Typically, the nanostructures are made of a metallic material, such as an elemental metal (e.g., transition metals) or a metal compound (e.g., metal oxide). The metallic material can also be a bimetallic material or a metal alloy, which comprises two or more types of metal. Suitable metals include, but are not limited to, silver, gold, copper, nickel, gold-plated silver, platinum and palladium.

The nanostructures can be of any shape or geometry. The morphology of a given nanostructure can be defined in a simplified fashion by its aspect ratio, which is the ratio of the length over the width and/or height of the nanostructure. For instance, certain nanostructures are isotropically shaped (i.e., aspect ratio=1). Typical isotropic nanostructures include nanoparticles. In preferred embodiments, the nanostructures are anisotropically shaped (i.e., aspect ratio≠1). The anisotropic nanostructure typically has a longitudinal axis along its length. Exemplary anisotropic nanostructures include nanowires, nanorods, and nanotubes, as defined herein.

The nanostructures can be solid or hollow. Solid nanostructures include, for example, nanoparticles, nanorods and nanowires (“NWs”). NWs typically refers to long, thin nanostructures having aspect ratios of greater than 10, preferably greater than 50, and more preferably greater than 100. Typically, the nanowires are more than 500 nm, more than 1 μm, or more than 10 μm long. “Nanorods” are typically short and wide anisotropic nanostructures that have aspect ratios of no more than 10. Although the present disclosure encompasses any type of nanostructure, for the sake of brevity, silver nanowires will be described as an example.

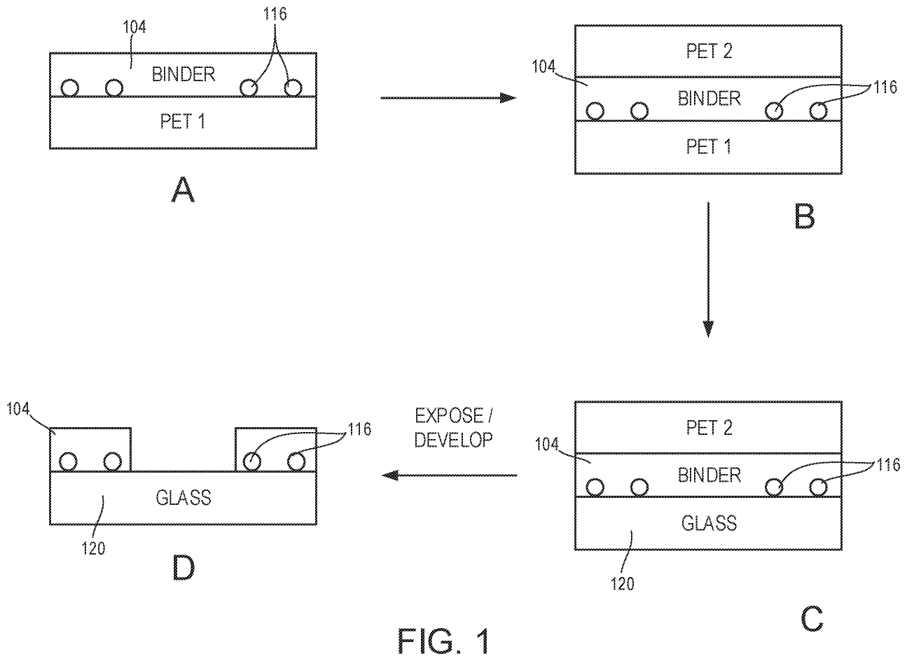

With reference to FIG. 1, example stages A-D that occur within an example method for forming and utilizing a transfer film to create a nanostructure (e.g., nanowire) film are shown. At stage A, a binder 104 is coated onto a first plastic (e.g., polyethylene terephthalate (PET)) substrate PET1. The binder 104 includes a polymeric carrier material that is reactive to light. For example, the carrier can be a photoresist that crosslinks or otherwise cures in response to being exposed to ultraviolet light, or to a light of another wavelength. The presence of a photoinitiator is often required for this photocuring to occur.

It is to be appreciated that example use of photoresist is just an example and that other examples of photosensitivity are contemplated and within this disclosure. As such photosensitive includes examples of negative and positive resists chemistries. The term photosensitive is to be interpreted as encompassing photocurable and also other processes.

The binder 104 also includes a plurality of example silver nanowires 116 suspended therein. It is possible that the nanowires 116 can settle toward the substrate PET 1, or alternatively the nanowires can be surrounded by the binder and separated from the surface of the substrate PET 1. Nonetheless, it is to be appreciated that the position of the nanowires 116 is merely an example, that the nanowires 116 may be at a different position (e.g., at or toward the middle and away from the substrate PET 1), and thus the position on the nanowires 116 need not be a specific limitation upon the present disclosure. Moreover, it is to be appreciated that the shown thickness of the binder 104 is merely an example and that the thickness of the binder can be lower, the same, or higher than the diameter of nanowires 116. Thus, binder thickness need not be a specific limitation upon the present disclosure. Further, the location of the nanowires 116 within the binder 104 may be dependent upon the thickness of the binder. Of course, the content as shown is only an example and need not be a specific limitation upon the present disclosure.

Focusing back to FIG. 1, the binder 104 is subsequently dried, and a protective cover, interchangeably referred to herein as the donor substrate PET 2, is applied over the binder 104 including the silver nanowires 116, as shown at stage B in FIG. 1. Alternatively, after coating and drying of the binder including a plurality of silver nanowires, another photosensitive binder (also called an overcoat) can be coated on top of the first binder/nanowires film. This second binder material may or may not intermix with the first binder material.

To transfer the binder 104 including the silver nanowires 116 to a device, the substrate PET 1 is removed, and the remaining assembly is placed atop a receiver substrate such as glass 120 provided to the device, as shown at stage C of FIG. 1. At this stage, the binder 104 is in contact with the glass 120. Pressure and heat can be applied so that the binder 104 adheres well to the receiver substrate 120. Either before or after the cover PET 2 is removed, the photosensitive polymeric material of the binder 104 is patterned through exposure to a suitable wavelength of light as part of a photolithographic process.

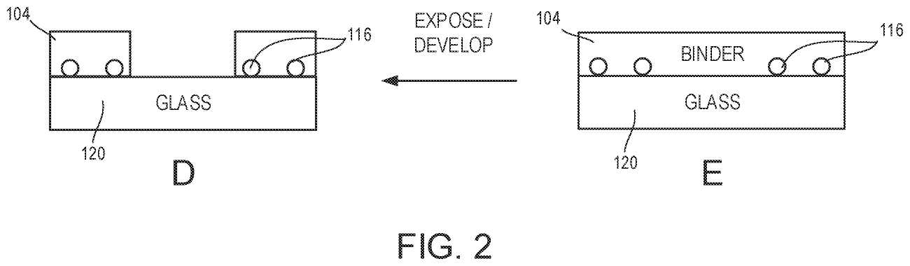

With reference to the example of FIG. 2, a binder 104 is directly coated onto a rigid substrate 120 such as glass or a flexible substrate such as PET or COP, as shown in stage E. It is worth mentioning that, similar to the example of FIG. 1, the shown content of FIG. 2 is merely an example. As such, the location of the nanowires 116 can varied (e.g., settled downward as shown in FIG. 2 or up toward the middle). Also, the thickness of the binder 104 can be varied (e.g., the binder thickness can be lower, the same, or higher than the diameter of nanowires 116). Further, the location of the nanowires 116 within the binder 104 may be dependent upon the thickness of the binder. Of course, all of these aspects/examples need not be a specific limitation upon the present disclosure.

Focusing back to FIG. 2, the binder 104 includes a polymeric carrier material that is reactive to light. For example, the carrier can be a photoresist that crosslinks or otherwise cures in response to being exposed to ultraviolet light, or to a light of another wavelength. The presence of a photoinitiator is often required for this photocuring to occur. The binder 104 also includes a plurality of silver nanowires 116 suspended therein, which may settle or not toward the glass or plastic substrate 120. The binder 104 is subsequently dried, then patterned through exposure to the suitable wavelength of light as part of a photolithographic process.

With the polymeric material of the binder 104 exposed to light through a mask, the polymeric material is developed with a developing solution that also includes an etchant that etches away silver nanowires. The role of the etchant is to facilitate the removal of the remaining nanowires which could be held in place by being entangled together. Development of the polymeric material of the binder 104 with such a developing solution removes the portions of the polymeric material that were not exposed to the exposure light, and thus removes also all or some of the silver nanowires present in the polymeric binder material, assuming that the polymeric material is a negative type resist. For other embodiments, portions of a positive type resist polymeric material that were exposed to light are removed during development. However, because the developing solution also includes the silver nanowire etchant, the development of the binder 104 also etches away residual nanowires on the glass 120 that could potentially cause a short circuit between adjacent patterned lines. The resulting developed binder 104 is shown at stage D in FIG. 1 and FIG. 2.

When the photosensitive binder material 104 is a negative type resist, a developing solution can be an organic solvent which is a good solvent for the uncured monomers. These monomers can be acrylic-type or epoxy-type. Common polar organic solvents such as acetone or PGMEA are suitable as developers. In addition, the organic solvent developer can contain a material to etch away silver nanowires in the uncured region of the binder material 104. Oxidizers such as transition metal salts, peroxides, organic acids, or complexing agents for silver in presence of oxygen may be used for this purpose, The organic solvent developer itself can also be a complexing agent for silver so that it can act as an etchant for silver in the presence of an oxidizer like oxygen. An example of such developer is monoethanolamine MEA.

When the photosensitive binder material 104 is a negative type resist containing acrylic acid moieties, the unexposed binder material can often be developed with an aqueous base solution such as sodium carbonate, sodium hydroxide, ammonium hydroxide, tetramethylammonium hydroxide TMAH and the like. An example of a developing solution containing a silver nanowire etchant is aqueous ammonia in the presence of oxygen. Another example can be sodium carbonate with a complexing base such as ammonia in the presence of oxygen. Another example includes a base such as potassium hydroxide in combination with ammonia and oxygen (from the air).

Other examples of alkaline developers having the ability to etch silver nanowires are sodium perborate, sodium percarbonate, sodium persulfate, hydrogen peroxide, used alone or in conjunction with common aqueous base solutions such as the carbonates or the hydroxides of alkali metals.

The photosensitive binder material 104 can also be a water-soluble, negative type resist containing a hydroxyl-containing polymer such as PVA or hydroxypropylmethylcellulose, a crosslinker, and a photoacid generator. Such materials are described in Chem. Mater., 1999, 11 (3), pp 719-725 DOI: 10.1021/cm980603y. Another example of a water-soluble negative type resist can be found in Chem. Mater., 1997, 9 (8), pp 1725-1730 DOI: 10.1021/cm9604165. In these cases, the unexposed photoacid generator can potentially be the etchant for the silver nanowires.

Accordingly, the present disclosure also provides a transparent, electrically-conductive film made by the method. The transparent, electrically-conductive film includes a substrate, a binder in a pattern on the substrate, with the pattern having edges, and metal nanostructures suspended in the binder. The nanostructures at pattern edges are truncated. The pattern has edges created by photolithography wherein binder material and nanostructures are etched off by a solution that includes a component that etches the metal of the nanostructures.

It is to be appreciated that the method of forming a transparent, electrically-conductive film as provided by the present disclosure provided a film that has desirable attributes. The nanostructures at pattern edges are truncated and thus the truncation helps provide very clean, distinct pattern edges. The truncation helps prevent stray nanostructures extending out from the pattern edges. Such is due to the pattern edges being created by photolithography wherein binder material and nanostructures are etched off by a solution that includes a component that etches the metal of the nanostructures.

Unless specified otherwise, “first,” “second,” and/or the like are not intended to imply a temporal aspect, a spatial aspect, an ordering, etc. Rather, such terms are merely used as identifiers, names, etc. for features, elements, items, etc. For example, a first object and a second object generally correspond to object A and object B or two different or two identical objects or the same object.

Moreover, “example” is used herein to mean serving as an instance, illustration, etc., and not necessarily as advantageous. As used herein, “or” is intended to mean an inclusive “or” rather than an exclusive “or.” In addition, “a” and “an” as used in this application are generally be construed to mean “one or more” unless specified otherwise or clear from context to be directed to a singular form. Also, at least one of A and B and/or the like generally means A or B or both A and B. Furthermore, to the extent that “includes,” “having,” “has,” “with,” and/or variants thereof are used in either the detailed description or the claims, such terms are intended to be inclusive in a manner similar to the term “comprising.”

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing at least some of the claims.

Various operations of embodiments are provided herein. The order in which some or all of the operations are described herein should not be construed as to imply that these operations are necessarily order dependent. Alternative ordering will be appreciated by one skilled in the art having the benefit of this description. Further, it will be understood that not all operations are necessarily present in each embodiment provided herein. Also, it will be understood that not all operations are necessary in some embodiments.

Also, although the disclosure has been shown and described with respect to one or more implementations, equivalent alterations and modifications will occur to others skilled in the art based upon a reading and understanding of this specification and the annexed drawings. The disclosure includes all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A transfer method of forming a transparent, electrically-conductive film, the method comprising:
providing a region of a donor substrate with a binder including metal nanostructures suspended in a photosensitive polymeric material;
applying the donor substrate and the binder onto a receiver substrate;
removing the donor substrate from the binder applied onto the receiver substrate;
using photolithography to pattern the binder; and
developing the patterned binder using a developing fluid that: (i) removes a portion of the photosensitive polymeric material according to a pattern of the binder, and (ii) includes a nanostructure etchant that provides for etching of the metal nanostructures.

2. The method as set forth in claim 1, wherein the developing fluid develops the patterned binder and etches the metal nanostructures as part of a single step.

3. The method as set forth in claim 1, wherein the developing fluid includes sodium carbonate and a complexing base in the presence of oxygen.

4. The method as set forth in claim 1, wherein the developing fluid includes ammonia in the presence of oxygen.

5. The method of claim 1, wherein the developing fluid includes a base and an oxidizing agent.

6. The method as set forth in claim 1, wherein nanostructure etchant truncates the metal nanostructures at pattern edges.

7. The method as set forth in claim 1, wherein nanostructure etchant prevents nanostructures extending out from the pattern edges.

8. The method as set forth in claim 1, wherein the nanostructures are nanowires.

9. A method of forming a transparent, electrically-conductive film, the method comprising:
providing a region of a substrate with a binder including metal nanostructures suspended in a photosensitive polymeric material;
using photolithography to pattern the photosensitive polymeric material; and
developing the patterned binder using a developing fluid that: (i) removes a portion of the photosensitive polymeric material according to a pattern of the binder, and (ii) includes a nanostructure etchant that etches the metal nanostructures.

10. The method as set forth in claim 9, wherein the developing fluid develops the patterned binder and etches the metal nanostructures as part of a single step.

11. The method as set forth in claim 9, wherein the developing fluid includes sodium carbonate and a complexing base in the presence of oxygen.

12. The method as set forth in claim 9, wherein the developing fluid includes ammonia in the presence of oxygen.

13. The method as set forth in claim 9, wherein the developing fluid includes a base and an oxidizing agent.

14. The method as set forth in claim 9, wherein nanostructure etchant truncates the metal nanostructures at pattern edges.

15. The method as set forth in claim 9, wherein nanostructure etchant prevents nanostructures extending out from the pattern edges.

16. The method as set forth in claim 9, wherein the nanostructures are nanowires.

17. A transparent, electrically-conductive film comprising:
a substrate;
a binder in a pattern on the substrate, the pattern having edges; and
metal nanostructures suspended in the binder, wherein nanostructures at pattern edges are truncated;
the pattern having edges created by photolithography wherein binder material and nanostructures are etched off by a solution that includes a component that etches the metal of the nanostructures.

18. The film as set forth in claim 17, wherein the nanostructures do not extend out from the pattern edges.

19. The film as set forth in claim 17, wherein the nanostructures are nanowires.
